(19) United States
(12) Patent Application Publication
(10) Pub. No.: US 2005/0238033 A1
(43) Pub. Date: Oct. 27, 2005

(54) Connection system, information supply apparatus, connection method and program

(76) Inventors: Shiro Sakamoto, Tokyo (JP); Susumu Yoshida, Tokyo (JP); Takanori Amano, Tokyo (JP)

Correspondence Address: HERSHKOVITZ & ASSOCIATES, 1725 I STREET NW, SUITE 300, WASHINGTON, DC, 20006, US

(21) Appl. No.: 11/071,263

(22) Filed: Mar. 4, 2005

Related U.S. Application Data
(63) Continuation of application No. PCT/JP03/11290, filed on Sep. 4, 2003.

(30) Foreign Application Priority Data
Sep. 4, 2002 (JP) JP 2002-259274

(51) Int. Cl. H04L 12/26; G06F 11/00; H04J 1/16; H04L 12/56; G08C 15/00; H04J 3/14; H04L 1/00; G01R 31/08; H04L 12/28

(52) U.S. Cl. 370/401; 370/229

(57) ABSTRACT

It is an object of the present invention to access to a closed network from an open network while maintaining secrecy of the closed network. In order for the object, a relay positioned in an open network receives user identifying information as a request for connecting to an information providing apparatus positioned in a closed network from an external terminal. The information providing apparatus sends a confirmation request for confirming whether or not a connection request from the external terminal exists to the relay regularly. In case of receiving, the relay outputs the stored user identifying information to the information providing apparatus. The information providing apparatus receives the user identifying information from the relay and determines whether or not a connection to the external terminal can be allowed on the basis of the user identifying information.

### BACKGROUND OF THE INVENTION

1. Field of the Invention

The present invention relates to a connecting system, an information providing apparatus, a connecting method, and a machine readable medium storing thereon a computer program for connection. More particularly, the present invention relates to a connecting system for connecting a terminal on an open network to an apparatus in a closed network, an information providing apparatus, a connecting method, and a machine readable medium storing thereon a computer program for connection.

2. Related Art

As importance of information for society becomes greater, consolidation of communication infrastructure is advanced. For example, an open network such as the internet establishes its position as communication infrastructure of general society. Further, in many cases, a company establishes its own closed network which is closed against the outside of the company in order to observe secrecy of information and satisfy requirement of co-ownership of information within the company.

Since a closed network is connected to an open network via a firewall, generally, a terminal of the outside of the closed network cannot access to the closed network.

Sometimes, when a person is out, he/she wants to take out contents kept within the closed network. Therefore, there exists a need for enabling to access to a closed network from an open network while maintaining secrecy of the closed network.

Accordingly, it is an object of the present invention to provide a connecting system, an information providing apparatus, a connecting method, and a machine readable medium storing thereon a computer program for connection, which are capable of overcoming the above drawbacks accompanying the conventional art. The above object can be achieved by combinations described in the independent claims. The dependent claims define further advantageous and exemplary combinations of the present invention.

### SUMMARY OF THE INVENTION

According to the first aspect of the present invention, a connecting system includes: an information providing apparatus positioned in a closed network; a relay positioned in an open network for relaying a connection to the information providing apparatus from an external terminal, which is a user terminal, connected to an open network; and a router for connecting the open network and the closed network, wherein the relay includes: a connection request holding unit for receiving and storing a user identifying information, which identifies the user, as a request for connecting to the information providing apparatus from the external terminal; and a connection request outputting unit for outputting the user identifying information stored in the connection request holding unit to the information providing apparatus in case a connection confirming request, which has an indication to confirm presence of a connection request from the external terminal, is received from the information providing apparatus, and the information providing apparatus includes: a contents managing unit for receiving and storing a content, which should be provided to the user, from another information processing apparatus positioned in the closed network; a connection request confirming unit for sending the connection confirming request to the relay regularly; a connection determining unit for receiving the user identifying information from the connection outputting unit of the relay and determining whether or not a connection to the external terminal can be made on the basis of the user identifying information; and a connection performing unit for connecting to the external terminal and providing the content to the external terminal in case the connection determining unit determines that the connection can be made.

According to the connecting system, the router may deny a connection to the closed network from the open network and allows a connection to the open network from the closed network.

The open network can be connected from a portable communication terminal which is the external terminal, the closed network can not be connected from the portable communication terminal, and the connection request holding unit of the relay may receive and store the user identifying information from the portable communication terminal.

The relay may further include a software identifying information storing unit for storing software identifying information, which identifies software operating on the relay, the connection request outputting unit of the relay may output the software identifying information with the user identifying information, and the connection determining unit of the information providing apparatus may further receive the software identifying information and make a connection to the external terminal only in case the user identifying information and the software identifying information are registered in the information providing apparatus previously.

The information providing apparatus may further include a contents managing unit for corresponding the content, which should be provided to the user, to each user, the connection request outputting unit of the relay further receives contents specifying information for specifying the content, which should be provided to the user, from the external terminal and outputs it to the information providing apparatus, the connection performing unit of the information providing apparatus may further receive the contents specifying information outputted from the connection request outputting unit and determine whether or not the connection to the external terminal can be made by using the received contents specifying information, and the connection performing unit of the information providing apparatus may send the content to the external terminal in case the connection determining unit issues a connection allowance.

The information providing apparatus may further include: an information format corresponding unit for corresponding the kind of the external terminal to an information format which can be processed by the external terminal; and a converting unit for receiving the kind of the external terminal and converting the content, which should be provided to the user, into the information format which can be processed by the external terminal, and the connection performing unit of the information providing apparatus may send the converted content to the external terminal.

The information providing apparatus may further include a contents managing unit connected to a simulation system performing a simulation computation on the closed network for regularly acquiring the computation result of the simulation and/or the computation process as the content, and the connection performing unit of the information providing apparatus may provide the computation result and/or the computation process acquired by the contents managing unit to the external terminal.

The information providing apparatus may further include: a content managing unit for managing mail sent to an internal terminal of the user connected to the closed network; and a converting unit for converting the mail into a language which can be interpreted by a Web browser, and the connection performing unit of the information providing apparatus may convert the mail sent to the internal terminal of the user into the language which can be interpreted by the Web browser and send it to the external terminal in case mail request information requesting the mail sent to the user is received.

According to the second aspect of the present invention, an information providing apparatus positioned in a closed network connected to an open network via a router, includes: a relay positioned in the open network, the relay include a connection request confirming unit for requesting regularly to the relay a user identifying information as a request for connecting to the information providing apparatus, the user identifying information being received from an external terminal which is a user terminal, can be connected to the open network and can not be connected to the closed network; a connection determining unit for receiving the user identifying information from the relay and determines whether or not a connection to the external terminal can be made on the basis of the user identifying information; and a connection performing unit for connecting to the external terminal on the basis of the determination of the connection determining unit.

The information providing apparatus may be positioned in the closed network to which a portable communication terminal can not connect.

The connection determining unit may further receives software identifying information for identifying software operating on the relay and determine whether or not a connection to the external terminal can be made on the basis of the user identifying information and the software identifying information.

The information providing apparatus may further include a contents managing unit for corresponding a content, which should be provided to the user, to the user, wherein the connection performing unit may further receive contents specifying information for specifying the content from the user via the relay and determines whether or not the connection to the external terminal can be made on the basis of the received contents specifying information, and the connection performing unit sends the content to the external terminal in case the connection determining unit issues a connection allowance.

The information providing apparatus may further include an information format corresponding unit for corresponding the kind of terminal to converted information format, and a converting unit for receiving the kind of the external terminal and converting the content, which should be provided to the user, into the information format which can be processed by the external terminal by using the information format corresponding unit, wherein the connection performing unit may send the converted content to the external terminal.

The information providing apparatus may further include a contents managing unit connected to a simulation system performing a simulation computation on the closed network for regularly acquiring the computation result of the simulation and/or the computation process as the content, wherein the connection performing unit may provide the computation result and/or the computation process acquired by the contents managing unit to the external terminal.

The information providing apparatus may further include: a contents request receiving unit for receiving mail request information which requests mail sent to the user; a contents managing unit for managing the mail sent to an internal terminal of the user connected to the closed network; and a converting unit for converting the mail into a language which can be interpreted by a Web browser, wherein the connection performing unit may convert the mail sent to the internal terminal of the user into the language which can be interpreted by the Web browser and send it to the external terminal in case a mail request information.

According to the third aspect of the present invention, a connecting method for connecting an information providing apparatus in a closed network and an external terminal, which is a user terminal, connected to an open network, the open network being connected to the closed network via a router, includes the steps of: receiving and storing a user identifying information for identifying the user as a request for connecting to the information providing apparatus from an external terminal by a relay in the open network; sending a connection confirming request, which has an indication to confirm presence of a connection request from the external terminal, regularly to the relay by the information providing apparatus; outputting the user identifying information stored in a connection request holding unit to the information providing apparatus in case the connection confirming request is received from the information providing apparatus by the relay; and receiving the user identifying information from the relay, determining whether or not a connection to the external terminal can be made on the basis of the user identifying information; and connecting to the external terminal by the information providing apparatus.

According to the fourth aspect of the present invention, machine readable medium storing thereon a computer program for connecting to an external terminal, which is a user terminal, can be connected to an open network and can not be connected to a closed network, from a closed network connected to the open network via a router though a relay in the open network, the program includes: a connection request confirming function for regularly requesting a user identifying information received by the relay from the external terminal as a request for connecting to the computer to the relay; a connection determining function for receiving the user identifying information from the relay and determining whether or not a connection to the external terminal can be made on the basis of the user identifying information; and a connection performing unit for making a connection to the external terminal on the basis of the determination result of the connection determining function.

The summary of the invention does not necessarily describe all necessary features of the present invention. The present invention may also be a sub-combination of the features described above.

### BRIEF DESCRIPTION OF THE DRAWINGS

FIG. 1 shows the configuration of a connecting system according to a first embodiment of the present invention.

FIG. 2 is a block diagram showing the configuration of a relay 100.

FIG. 3 shows the construction of information stored in an external user information storing unit 110 as a type of table.

FIG. 4 shows the construction of information stored in a software identifying information storing unit 120 as a type of table.

FIG. 5 shows the construction of information stored in a connection correspondence information storing unit 130 as a type of table.

FIG. 6 shows the construction of information held by a connection request holding unit 140 as a type of table.

FIG. 7 is a block diagram showing the configuration of an information providing apparatus 300.

FIG. 8 shows a data construction of information stored in an internal user information storing unit 320 as a type of table.

FIG. 9 shows a data construction of information stored in a contents managing unit 330 as a type of table.

FIG. 10 shows the construction of information stored in an information format corresponding unit 340 as a type of table.

FIG. 11 is a flowchart showing an example of operation of the connecting system of FIG. 1.

FIG. 12 is a flowchart describing an example of S360 in FIG. 11 in detail.

FIG. 13 is a flowchart describing another example of S360 of FIG. 11 in detail.

FIG. 14 is a flowchart of the information providing apparatus 300 after an external terminal 20 requires simulation computation result.

### DETAILED DESCRIPTION OF THE INVENTION

The invention will now be described based on the preferred embodiments, which do not intend to limit the scope of the present invention, but exemplify the invention. All of the features and the combinations thereof described in the embodiment are not necessarily essential to the invention.

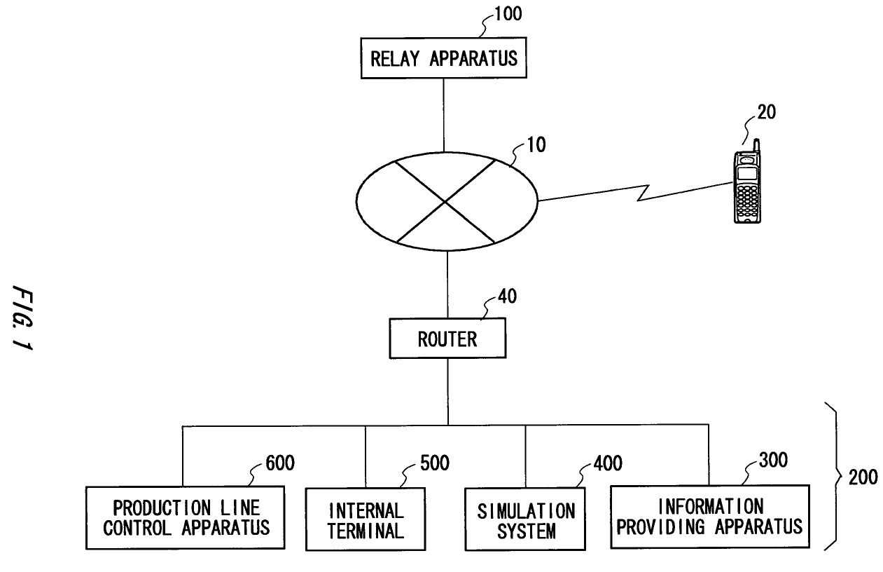

FIG. 1 shows the configuration of a connecting system according to a first embodiment of the present invention. The connecting system makes a connection from an external terminal 20 to a closed network 200 and connects a relay 100 and the closed network connected with an open network 10.

The open network 10 is, for example, the internet. The external terminal 20 is, for example, a mobile communication terminal which is connectable to a mobile communication network, but may be a fixed terminal.

The closed network 200 includes an information providing apparatus 300, a simulation system 400, an internal terminal 500, and a production line control apparatus 600, for example. The information providing apparatus 300 acquires a simulation computation result and/or a simulation computation process from the simulation system 400. Further, the information providing apparatus 300 acquires mail sent to the internal terminal 500 from the internal terminal 500. Mail server may be provided in addition to the closed network 200. In this case, the information providing apparatus 300 may acquire mail addressed to internal terminal from the mail server.

Further, the closed network 200 connects to the open network 10 via a router 40. The router 40 passes a request for connecting from the closed network 200 to the open network 10, but, does not pass a request for connecting from the open network 10 to the closed network 200. Further, it is not possible to make a connection from the mobile communication terminal connected to a mobile communication terminal.

According to this configuration, the external terminal 20 sends user identifying information for identifying a user of the external terminal 20, external terminal identifying information for identifying the external terminal 20, and information providing apparatus identifying information for identifying the information providing apparatus 300, to the relay 100 as a request for connecting to the closed network 200. The relay 100 stores the received information.

Further, the information providing apparatus 300 confirms whether or not a request for connecting to the information providing apparatus 300 exists through the relay 100 regularly, for example, every one (1) second. Then, the information providing apparatus 300 receives the user identifying information, the external terminal identifying information, and the information providing apparatus identifying information from the relay 100, and determines whether or not a connection of the external terminal is allowable on the basis of the received information. Then, the information providing apparatus 300 connects to the external terminal 20 via the relay 100 or directly on the basis of the determination and sends mail addressed to the internal terminal 500, a computation result and/or a computation process of the simulation system 400, production line data managed by the production line control apparatus 600, and the like.

Therefore, since the present connecting system makes a connection from the information providing apparatus 300 to the external terminal 20 which has requested the connection, it is possible to connect the external terminal 20 and the information providing apparatus 300 on the basis of the request for the connection from the external terminal 20 which is outside of the closed network while making the closed network secure. Further, since the router 40 does not pass a request for connecting from the open network 10 to the closed network 200, security of the closed network is improved.

Further, the present connection supporting system may include a plurality of routers 40 and a plurality of closed networks 200.

Further, the external terminal identifying information may also be the user identifying information. Further, the external terminal identifying information may be a phone number assigned to the external terminal 20, mail address, or a device number of the external terminal 20.

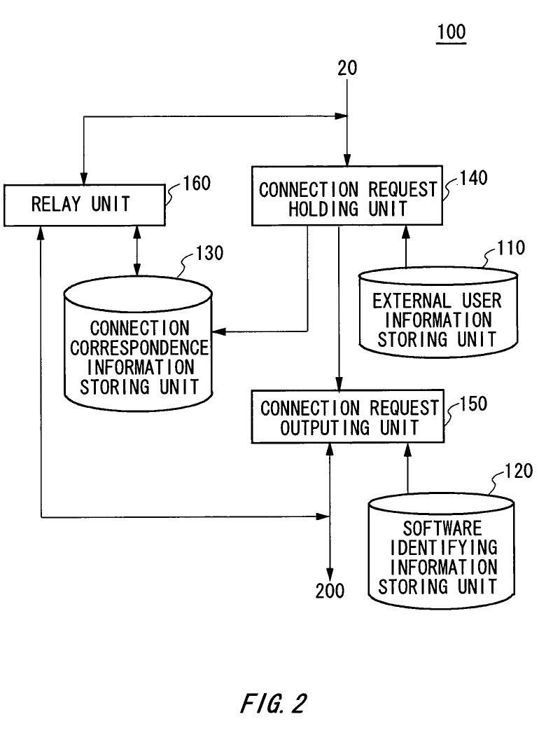

FIG. 2 is a block diagram showing the configuration of the relay 100. The relay 100 includes an external user information storing unit 110, a software identifying information storing unit 120, a connection correspondence information storing unit 130, a connection request holding unit 140, a connection request outputting unit 150, and a relay unit 160.

The external user information storing unit 110 stores user information which is information on a user of the external terminal 20. The user information is used for determining whether or not the relay 100 holds the request for connecting from the external terminal 20.

The software identifying information storing unit 120 stores software identifying information for identifying a communication software or an application software operating on the relay 100. The software identifying information is sent to the information providing apparatus 300 with the connection request and used for authentication process of the information providing apparatus 300.

The connection correspondence information storing unit 130 stores information for identifying an open side logic circuit which is a logic circuit provided in order for connection from the external terminal 20 to the relay 100 and a closed side logic circuit which is a logic circuit provided in order for connection from the information providing apparatus 300 to the relay 100 so that they correspond to each other. The information stored in the connection correspondence information storing unit 130 is used to connect the external terminal 20 and the information providing apparatus 300.

The connection request holding unit 140 is referred to the user information stored in the external user information storing unit 110 for user information received from the external terminal 20 during requesting a connection and determines whether or not it holds the connection request on the basis of the reference. Then, the connection request holding unit 140 holds the connection request according to the determination. Further, the connection request holding unit 140 makes information for identifying a logic circuit used for sending the connection request stored in the connection correspondence information storing unit 130 as the information for identifying the open side logic circuit between the external terminal 20 and the relay 100 so that the information corresponds to the external terminal 20.

The connection request outputting unit 150 receives information for confirming whether or not a connection request exists from the information providing apparatus 300, acquires the user information which is held as a request for connecting to the information providing apparatus 300 from the connection request holding unit 140, and outputs the information to the information providing apparatus 300.

If the relay unit 160 receives information instructing to make a connection to the external terminal 20 from the information providing apparatus 300, the relay unit 160 defines the logic circuit used for sending the information as a closed side logic circuit used for communication with the external terminal 20 and makes information identifying the closed side logic circuit stored in the connection correspondence information storing unit 130 with information identifying the open side logic circuit corresponding to the external terminal 20.

Then, the relay unit 160 sends information sent from the external terminal 20 via the open side logic circuit to the information providing apparatus 300 via the closed side logic circuit corresponding to the open side logic circuit, and information sent from the relay 100 via the closed side logic circuit to the external terminal 20 via the open side logic circuit corresponding to the closed side logic circuit. Therefore, the relay 100 can hold a request for connecting from the external terminal 20 to the information providing apparatus 300 in the closed network 200 as reservation state and output the request to the information providing apparatus 300 in case there is a request from the information providing apparatus 300. Further, it is possible to connect the information providing apparatus 300 with the external terminal 20 in case the information providing apparatus 300 responds to the connection request.

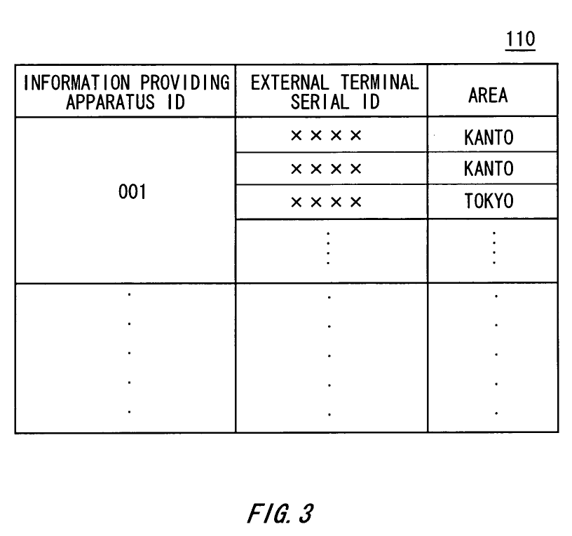

FIG. 3 shows the construction of information stored in the external user information storing unit 110 as a type of table. The external user information storing unit 110 stores information providing apparatus identifying information (information providing apparatus ID in the example of FIG. 3) and information for identifying an external terminal 20 which is allowed to connect to the information providing apparatus 300 (serial ID of external terminal 20 in the example of FIG. 3) so that they correspond to each other.

Therefore, the relay 100 does not send a request for connecting from an external terminal 20 which is not allowed to connect to the information providing apparatus 300 to the information providing apparatus 300.

Further, the external user information storing unit 110 may further store information for identifying an external terminal 20 with a locational area of the external terminal 20 where the external terminal 20 is allowed to connect. In this case, the connection request holding unit 140 of the relay 100 acquires information on the location of the external terminal 20 from the external terminal 20 or a management system of the mobile communication network, is referred to the area stored in the external user information storing unit 110 for the acquired information, and determines whether or not the connection request is to be held.

Therefore, if the external terminal 20 requests a connection at a place where the connection is not allowed in which case such the external terminal 20 passes to another's hand, the relay 100 can recognize that the request is improper.

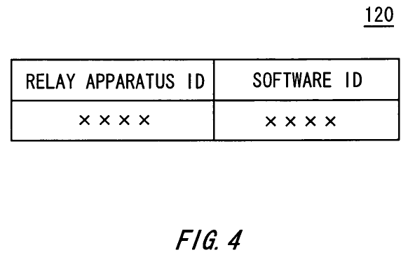

FIG. 4 shows the construction of information stored in the software identifying information storing unit 120 as a type of table. The software identifying information storing unit 120 stores relay identifying information for identifying the relay 100 and software identifying information for identifying software. Therefore, the relay 100 can output the software identifying information and/or the relay identifying information to the information providing apparatus 300 for authentication.

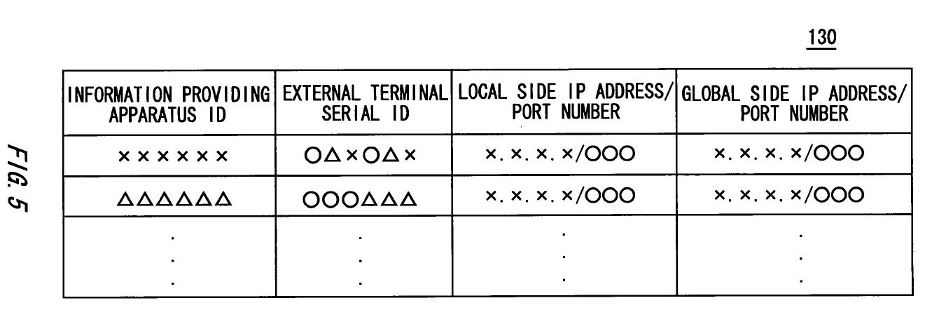

FIG. 5 shows the construction of information stored in the connection correspondence information storing unit 130 as a type of table.

The connection correspondence information storing unit 130 stores a global IP address and a port number used for communication between the external terminal 20 and the relay 100 as information for identifying the open side logic circuit. Further, the connection correspondence information storing unit 130 stores a global IP address and a port number of the router 400 as information for identifying the closed side logic circuit corresponding to the open side logic circuit. Each global IP address and each port number are acquired from an IP header and a TCP header of TCP/IP connection.

Further, the open side logic circuit identifying information and the closed side logic circuit identifying information are stored so as to correspond to information identifying each of the external terminal 20 and the information providing apparatus 300 connected via the open side logic circuit and the closed side logic circuit.

Therefore, since the relay unit 160 of the relay 100 can identify a logic circuit on the basis of a combination of the global IP address and the port number, it is possible to connect each of a plurality of external terminal 20 with the information providing apparatus 300.

Further, the global IP address and the port number for identifying the closed side logic circuit are managed to correspond to a local IP and a port number of the router 40.

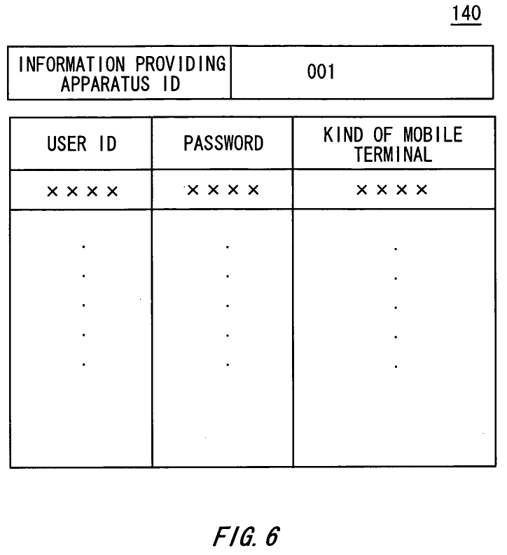

FIG. 6 shows the construction of information held by the connection request holding unit 140 as a type of table. The connection request holding unit 140 stores user information received from the mobile communication terminal 20 when the mobile communication terminal 20 requests a connection to each information providing apparatus 300. The stored user information includes user identifying information (user ID), a login password for the information providing apparatus 300, and the kind of the external terminal 20.

Therefore, the relay 100 can output user information of a user who sends a request for connecting to the information providing apparatus 300 to the information providing apparatus 300.

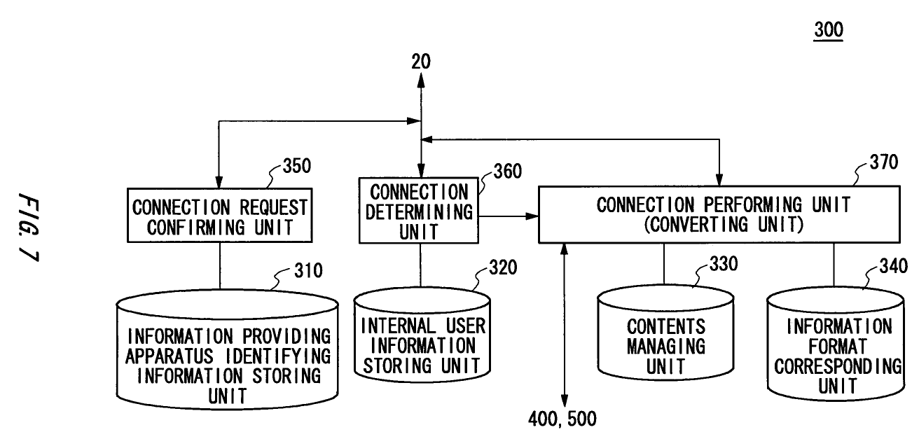

FIG. 7 is a block diagram showing the configuration of the information providing apparatus 300. The information providing apparatus 300 includes an information providing apparatus identifying information storing unit 310, an internal user information storing unit 320, a contents managing unit 330, an information format corresponding unit 340, a connection request confirming unit 350, a connection determining unit 360, and a connection performing unit 370. The connection performing unit 370 is also a converting unit.

The information providing apparatus identifying information storing unit 310 stores information providing apparatus identifying information for identifying the information providing apparatus 300. The internal user information storing unit 320 stores information for authenticating a user who sends a connection request.

The contents managing unit 330 receives contents which should be provided to the user from another information processing apparatus in the closed network and hold the contents. Further, the contents managing unit 330 stores information for controlling the contents which should be provided to the user. The information format corresponding unit 340 stores the kind of the external terminal 20 and a format of information which can be processed by the external terminal so that they correspond to each other.

The connection request confirming unit 350 retrieves the information providing apparatus identifying information from the information providing apparatus identifying information storing unit 310 and sends the information to the relay 100 together with information for inquiring whether or not a connection request exists regularly. Preferably, the sending interval is shorter than a period of timeout during which the external terminal 20 and the relay 100 are unconnected.

The connection determining unit 360 receives the connection request and the user information from the relay 100 and is referred to the internal user information storing unit 320 for the user information.

The internal user information storing unit 320 may previously register software identifying information of application software for allowing use of a user so that the information corresponds to identifying information of the user. In this case, the connection determining unit 360 determines whether or not a combination of the user information received with the connection request and the software identifying information registered in the internal user information storing unit 320. Then, the connection determining unit 360 determines whether or not a connection is possible on the basis of the reference.

In case the connection determining unit 360 determines that a connection is possible, the connection performing unit 370 connects with the external terminal 20 via the relay 100 and/or directly. Further, the connection performing unit 370 is referred to the contents managing unit 330 for contents required by the external terminal 20 and to acquire the contents and sends the contents via the relay 100 and/or directly. Here, the connection performing unit 370 acquires the kind of the external terminal 20 from the relay 100, determines the format of information which can be processed by the terminal of this kind on the basis of the information format corresponding unit 340, converts the contents into the determined format, and sends the converted contents to the external terminal 20.

Therefore, the information providing apparatus 300 can connect with the external terminal 20 which cannot be directly connected to the closed network 200 and provide contents in the closed network 200 to the user of the external terminal 20.

Further, since the identifying information of application software of the relay 100 is used when authentication for the connection is performed, it is difficult to suffer from hacking.

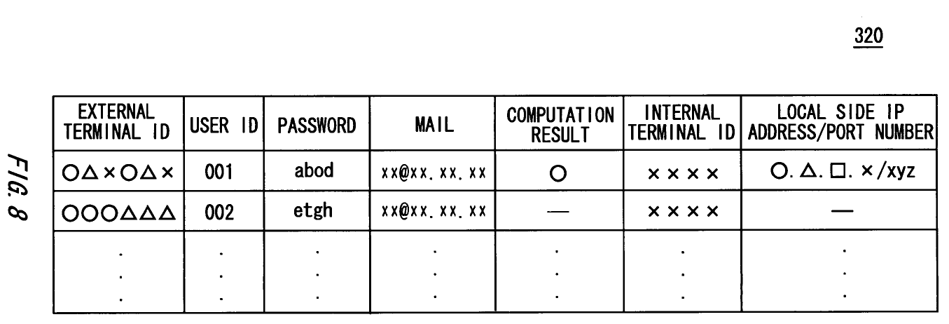

FIG. 8 shows a data construction of information stored in the internal user information storing unit 320 as a type of table. The internal user information storing unit 320 stores a combination of user identifying information of the user of the external terminal 20 and a password so that they correspond to the kind of the external terminal 20. In addition, the internal user information storing unit 320 stores mail address of the user and information for specifying a content which is allowed to be sent to the external terminal 20 of the user. This information is information on whether or not acquisition of computation result of the simulation system 400 is allowed or information for identifying the internal terminal 500 to which the user is allowed to connect (internal terminal ID in the example of FIG. 8).

Therefore, the information providing apparatus 300 can determine a content which should be provided to each user. Further, in case the user requests contents which the user is not allowed to use, it is possible to reject the connection request.

Further, the internal user information storing unit 320 stores information for identifying a logic circuit provided between the information providing apparatus 300 and the internal terminal 500 of a user, for example, a local IP address and a port number included in an IP header and a TCP header.

Therefore, the connection performing unit 370 can be referred to the internal user information storing unit 320, acquire a logic circuit in the closed network to the internal terminal 500 to which a connection is required, and connect the external terminal 20 and the internal terminal 500.

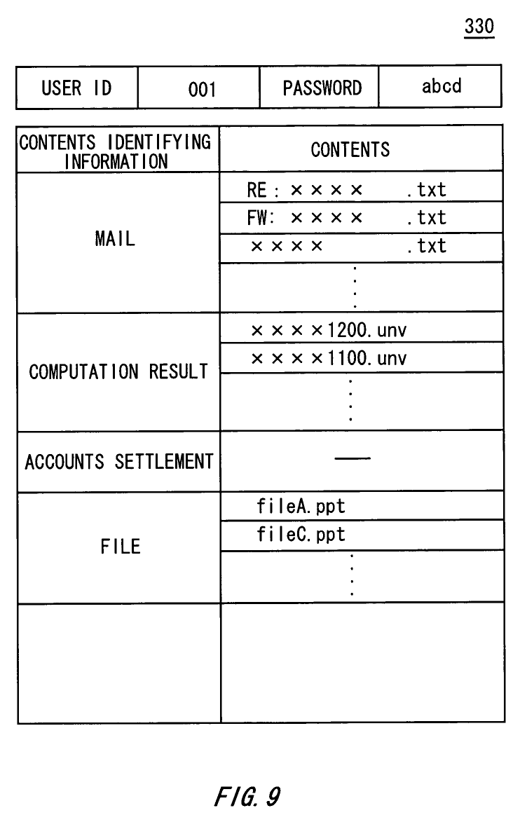

FIG. 9 shows a data construction of information stored in the contents managing unit 330 as a type of table. The contents managing unit 330 stores contents which should be provided to each user or information showing the place where the contents are. For example, the contents managing unit 330 acquires mail addressed to the internal terminal 500 used by the user from the mail server 700 shown in FIG. 1 and holds it. Further, the contents managing unit 330 acquires computation result and/or computation process of simulation performed by the user from the simulation system 400 regularly and holds the computation result and/or computation process. Further, the contents managing unit 330 stores information for specifying a file which the user is allowed to browse.

Therefore, even under a situation where the user can connect to only the open network 10, the information providing apparatus 300 can provide to the user with contents such as mail addressed to the internal terminal 500, computation result or computation process of simulation performed by the simulation system 400, and the like.

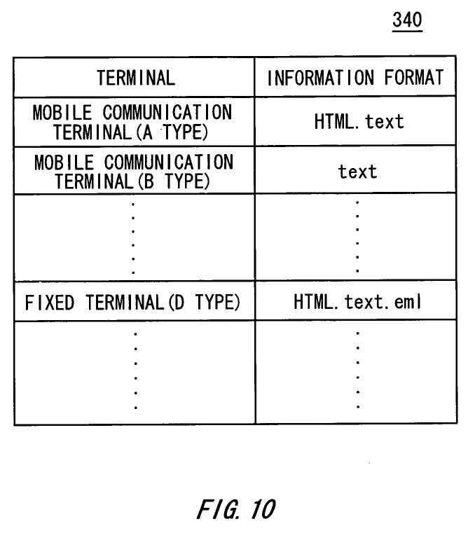

FIG. 10 shows the construction of information stored in the information format corresponding unit 340 as a type of table. The information format corresponding unit 340 makes the kind of a terminal correspond to a format of common use which can be processed by the terminal of this kind and stores them. For example, the information format corresponding unit 340 makes a mobile communication terminal which can connect to the internet correspond to a language which is interpretable by a Web browser such as HTML and stores the language. The kind of the terminal includes a fixed terminal.

Therefore, the information providing apparatus 300 can convert the format of information according to the kind of the external terminal 20 with which it connects and send the converted information to the external terminal 20.

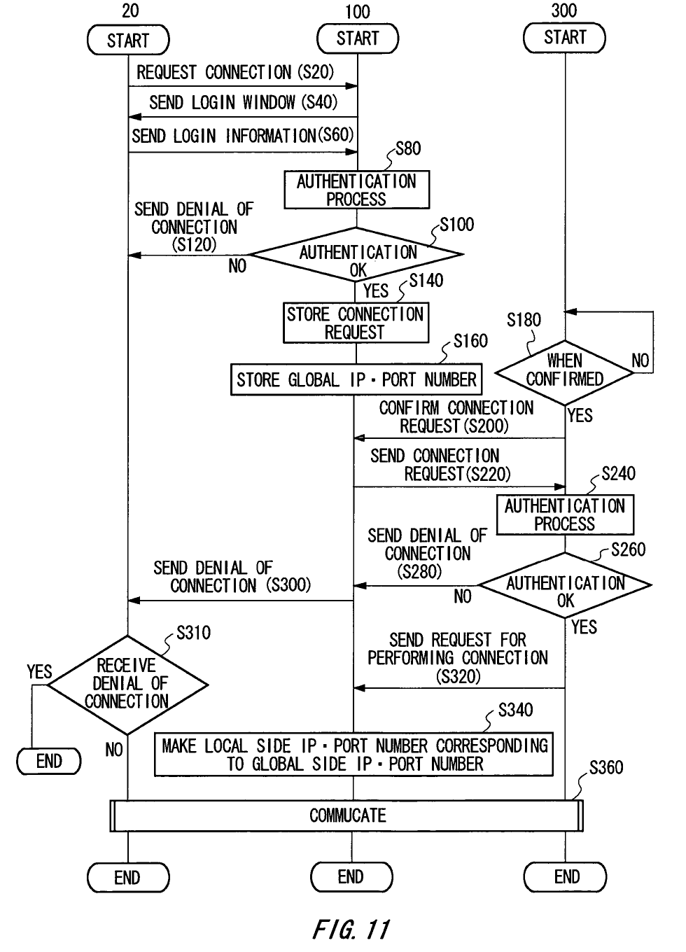

FIG. 11 is a flowchart showing an example of operation of the connecting system of FIG. 1. The external terminal 20 requires the relay 100 to connect itself to the closed network 200, that is, the information providing apparatus 300 (S20). The relay 100 sends a login window for inputting information needed for connection authentication to the external terminal 20 (S40). The external terminal 20 sends information providing apparatus identifying information, user identifying information, password, etc., which are input by the user through the login window, the kind of the external terminal 20, a serial ID of the external terminal 20, and information for specifying required contents as login information (S60).

The connection request holding unit 140 of the relay 100 performs authentication process of the connection request on the basis of the information sent by the external terminal 20 (S80). The authentication process is performed, for example, by being referred to the external user information storing unit 110 for a combination of a serial ID of the external terminal 20 and the information providing apparatus identifying information.

In case the connection request is not authenticated (S100: No), the connection request holding unit 140 sends information showing whether on not the connection is allowed to the external terminal 20 (S120) and finishes operation (S310).

In case the connection request is authenticated (S100: Yes), the connection request holding unit 140 holds the information sent during S60 (S140). Further, in order to specify an open side logic circuit used for the connection between the external terminal 20 and the relay 100, the connection request holding unit 140 makes a global IP and a port number stored in the connection correspondence information storing unit (S160).

Further, at a timing of the connection request confirming unit 350 of the information providing apparatus 300 requests confirmation (S180: Yes), the connection request confirming unit 350 informs the relay 100 of confirming the connection request and sends the information providing apparatus identifying information to the relay 100 (S200).

The connection request outputting unit 150 of the relay 100 sends the user identifying information, the password, the kind of the external terminal 20, and the information for specifying required contents, which are stored to correspond to the received information providing apparatus identifying information, to the information providing apparatus 300 as a connection request (S220).

The connection determining unit 360 of the information providing apparatus 300 performs authentication process of the connection request on the basis of the information received from the connection request outputting unit 150 of the relay 100 (S240). The authentication process is performed by being referred to the internal user information storing unit 320 for the received information. In case of not being authenticated (S260: No), the connection determining unit 360 informs the external terminal 20 of denying a connection via the relay 100 (S280, S300).

In case of being authenticated (S260: No), the connection performing unit 370 of the information providing apparatus 300 sends a request for performing a connection to the external terminal 20 to the relay 100 (S320). The relay unit 160 of the relay 100 makes an IP address and a port number used for sending the request for performing a connection stored in the connection correspondence information storing unit 130 as an IP address and a port number and a port number for identifying a closed side logic circuit so that they correspond to the IP address and the port number used when a connection request is sent from the external terminal 20 (S340).

Then, the external terminal 20 and the information providing apparatus 300 communicates via the relay unit 160 in the relay (S360).

In other words, in case a connection is made from the external terminal 20 to the closed network, that is, the information providing apparatus 300, authentication process performed by the relay 100 and authentication process performed by the information providing apparatus 300 should be passed. Further, in order to establish a connection, the connection needs to be made from the information providing apparatus 300.

Therefore, if the connecting system of the present invention is used, it is possible to make a connection from an external terminal such as the external terminal 20 to the closed network 200 while maintaining secrecy of the closed network 200.

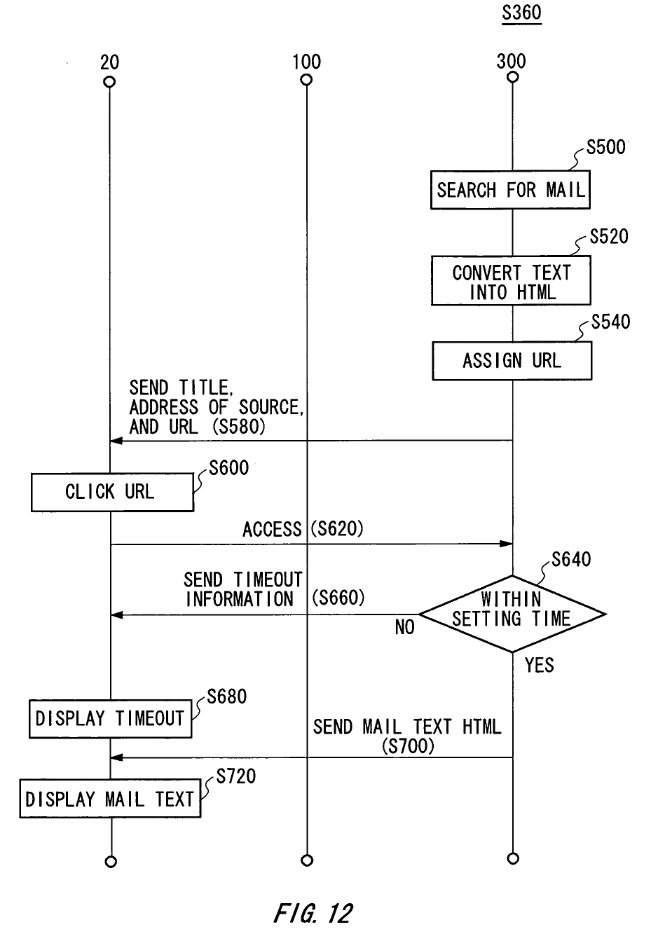

FIG. 12 is a flowchart describing an example of S360 in FIG. 11 in detail. The flowchart shows operation of sending mail addressed to the internal terminal 500 to the external terminal 20.

First, the connection performing unit 370 searches for mail addressed to the internal terminal 500 used by the user of the external terminal 20 (S500). Then, text of the mail is converted into HTML(S520), a URL is assigned (S540), and a title of the mail, an address of source of the mail, and the URL assigned in S540 are sent to the external terminal 20 via the relay 100 (S580).

If the external terminal 20 detects that the user clicks the URL (S600), it accesses to the information providing apparatus 300 according to the URL (S620).

In case a period from a time of sending in S580 to a time of access in S620 is larger than a predetermined time (S650: No), the connection performing unit 370 of the information providing apparatus 300 informs the external terminal 20 that it is a timeout and the text of the mail cannot be sent (S660). Then, the external terminal 20 displays that it is a timeout and the text of the mail cannot be sent (S680). The time to the timeout is, for example, the sum of an average period required for sending a URL, an average period of the user confirming the URL, and an average time of the external terminal 20 connecting to the information providing apparatus 300. Specifically, the time is one (1) minute.

In case a period from a time of sending in S580 to a time of access in S620 is smaller than the predetermined time (S650: Yes), the connection performing unit 370 of the information providing apparatus 300 sends the HTML of the mail text to the external terminal 20 (S680). Then, the external terminal 20 displays the mail text according to the received HTML (S720).

Therefore, it is possible to send text of mail addressed to the internal terminal 500 to the external terminal 20, even if the external terminal 20 does not have mail function. Further, since an available time is provided for the URL for browsing the mail text, it is possible to prohibit the URL from being sent illegally and thus the mail text from being accessed illegally.

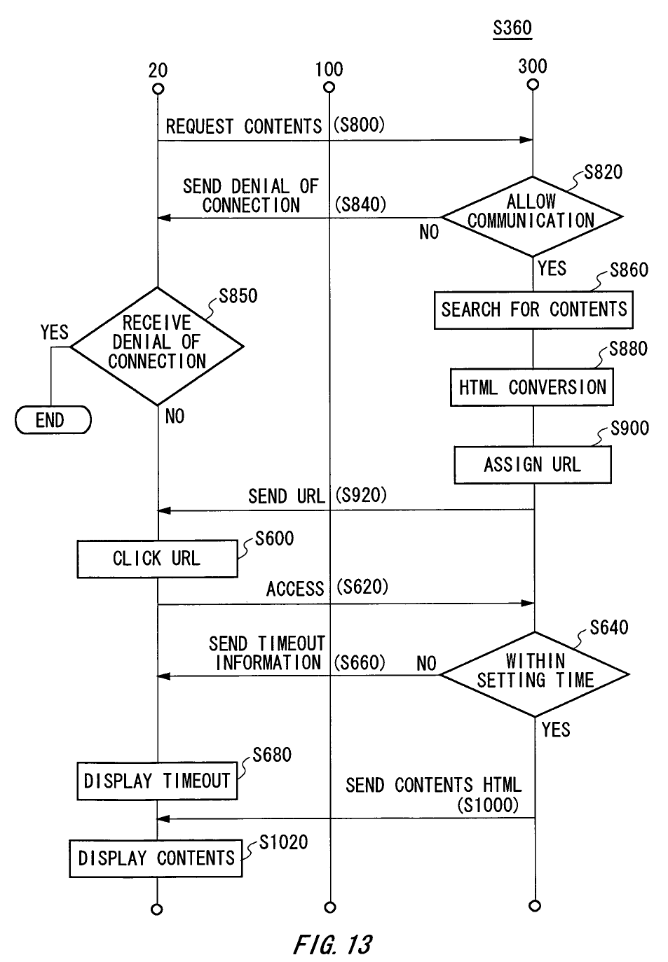

FIG. 13 is a flowchart describing another example of S360 of FIG. 11 in detail. The flowchart shows operation in case the external terminal 20 requires a specific content after the connection between the external terminal 20 and the information providing apparatus 300 is established.

The external terminal 20 sends information specifying contents for the information providing apparatus 300 and requires the specified content (S800). The specified content is, for example, a file managed by the information providing apparatus 300, a file managed by the internal terminal 500, that is, a request for connecting to the internal terminal 500, production line control data managed by the production line control apparatus 600, and the computation result or the computation process of simulation. Further, when the external terminal 20 requires a content, it may make the user input user identifying information and a password for acquiring the content and send the input information.

The connection performing unit 370 of the information providing apparatus 300 determines whether or not the content is allowed to be sent to the user of the external terminal 20 (S820). In case of not being allowed (S820: No), the connection performing unit 370 informs the information providing apparatus 300 that the content cannot be sent (S840), and finishes operation (S850).

In case of being allowed, the connection performing unit 370 is referred to the contents managing unit 330 for the required content and acquires the content on the basis of the reference. Here, in case computation result or computation process is required as a content, it is preferred to provide the latest computation result or the latest computation process as the content.

Then, the acquired content is converted into HTML(S880), a URL is assigned (S900), and the assigned URL is sent to the external terminal 20 (S920).

If the external terminal 20 detects that the user clicks the URL (S600), it accesses to the information providing apparatus 300 according to the URL (S620). Then, on condition that it is not a timeout (S640), the HTML showing the content is sent to the external terminal 20 (S1000). The external terminal 20 displays the content according to the received HTML (S1020).

Further, detailed description on a timeout and description on process when it is a timeout are omitted because they are the same as those of S640 to S660 in FIG. 12.

Therefore, if the external terminal requires a content which is not allowed to be sent, the information providing apparatus 300 denies sending the content. Therefore, the information providing apparatus 300 does not send a content which is not allowed to be sent, even after the connection is established.

Further, a display window based on an application program executed on the internal terminal 500 may be a content and an input to the application program may be information for specifying and requesting the content. In this case, the information providing apparatus 300 relays the input to the internal terminal 500, acquires result of operation based on the input from the internal terminal 500, and outputs the result to the external terminal 20. By this, it is possible to confirm operation of the application program executed on the internal terminal 500 form the external terminal 20.

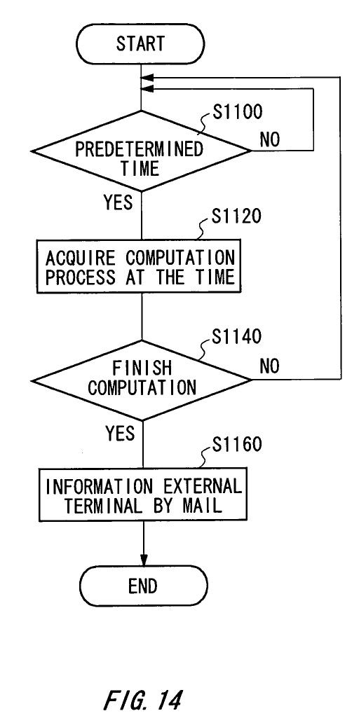

FIG. 14 is a flowchart of the information providing apparatus 300 after the external terminal 20 requires simulation computation result of the simulation system 400. The information providing apparatus 300 acquires the computation result from the simulation system 400 regularly (S1100 and S1120). Then, if the computation is finished, the information providing apparatus 300 sends mail informing the external terminal 20 which has required the computation result that the computation is finished (S1160).

Therefore, the user who performs simulation can know that the simulation is finished even in a situation where he/she cannot connect directly to the closed network 200.

Although the present invention has been described by way of exemplary embodiments, it should be understood that those skilled in the art might make many changes and substitutions without departing from the spirit and the scope of the present invention which is defined only by the appended claims.

As obvious from the above description, according to the present invention, it is possible to access to a closed network from an open network while maintaining secrecy of the closed network.

1. A connecting system comprising:
an information providing apparatus positioned in a closed network;
a relay positioned in an open network for relaying a connection to the information providing apparatus from an external terminal, which is a user terminal, connected to an open network; and
a router connected to the open network and the closed network for denying a connection to the closed network from the open network and allowing a connection to the open network from the closed network,
wherein said relay comprises:
a connection request holding unit for receiving and storing a user identifying information, which identifies the user, as a request for connecting to said information providing apparatus from the external terminal; and
a connection request outputting unit for outputting the user identifying information stored in said connection request holding unit to said information providing apparatus in case a connection confirming request, which has an indication to confirm presence of a connection request from the external terminal, is received from said information providing apparatus, and
said information providing apparatus comprises:
a contents managing unit for receiving and storing a content, which should be provided to the user, from another information processing apparatus positioned in the closed network;
a connection request confirming unit for sending the connection confirming request to said relay regularly;
a connection determining unit for receiving the user identifying information from said connection outputting unit of said relay and determining whether or not a connection to the external terminal can be made on the basis of the user identifying information; and
a connection performing unit for connecting to the external terminal and providing the content to the external terminal in case said connection determining unit determines that the connection can be made.

2. A connecting system as claimed in claim 1, wherein the open network can be connected from a portable communication terminal which is the external terminal, the closed network can not be connected from the portable communication terminal, and said connection request holding unit of said relay receives and stores the user identifying information from the portable communication terminal.

3. A connecting system as claimed in claim 1, wherein said relay further comprises a software identifying information storing unit for storing software identifying information, which identifies software operating on said relay, said connection request outputting unit of said relay outputs the software identifying information with the user identifying information, and said connection determining unit of said information providing apparatus further receives the software identifying information and makes a connection to the external terminal only in case the user identifying information and the software identifying information are registered in said information providing apparatus previously.

4. A connecting system as claimed in claim 1, wherein said information providing apparatus further comprises a contents managing unit for corresponding the content, which should be provided to the user, to each user, said connection request outputting unit of said relay further receives contents specifying information for specifying the content, which should be provided to the user, from the external terminal and outputs it to said information providing apparatus, said connection performing unit of said information providing apparatus further receives the contents specifying information outputted from said connection request outputting unit and determines whether or not the connection to the external terminal can be made by using the received contents specifying information, and said connection performing unit of said information providing apparatus sends the content to the external terminal in case the connection determining unit issues a connection allowance.

5. A connecting system as claimed in claim 1, wherein said information providing apparatus further comprises:
an information format corresponding unit for corresponding the kind of the external terminal to an information format which can be processed by the external terminal; and
a converting unit for receiving the kind of the external terminal and converting the content, which should be provided to the user, into the information format which can be processed by the external terminal, and
said connection performing unit of said information providing apparatus sends the converted content to the external terminal.

6. A connecting system as claimed in claim 1, wherein said information providing apparatus further comprises a contents managing unit connected to a simulation system performing a simulation computation on the closed network for regularly acquiring the computation result of the simulation and/or the computation process as the content, and said connection performing unit of said information providing apparatus provides the computation result and/or the computation process acquired by said contents managing unit to the external terminal.

7. A connecting system as claimed in claim 1, wherein said information providing apparatus further comprises:
a content managing unit for managing mail sent to an internal terminal of the user connected to the closed network; and
a converting unit for converting the mail into a language which can be interpreted by a Web browser, and said connection performing unit of said information providing apparatus converts the mail sent to the internal terminal of the user into the language which can be interpreted by the Web browser and send it to the external terminal in case mail request information requesting the mail sent to the user is received.

8. An information providing apparatus positioned in a closed network connected to an open network via a router, comprising:
a relay positioned in the open network, said relay comprising a connection request confirming unit for requesting regularly to said relay a user identifying information as a request for connecting to said information providing apparatus, the user identifying information being received from an external terminal which is a user terminal, can be connected to the open network and can not be connected to the closed network;
a connection determining unit for receiving the user identifying information from said relay and determines whether or not a connection to the external terminal can be made on the basis of the user identifying information; and
a connection performing unit for connecting to the external terminal on the basis of the determination of said connection determining unit.

9. An information providing apparatus as claimed in claim 8, wherein said information providing apparatus is positioned in the closed network to which a portable communication terminal can not connect.

10. An information providing apparatus as claimed in claim 8, wherein said connection determining unit further receives software identifying information for identifying software operating on said relay and determines whether or not a connection to the external terminal can be made on the basis of the user identifying information and the software identifying information.

11. An information providing apparatus as claimed in claim 8 further comprising a contents managing unit for corresponding a content, which should be provided to the user, to the user, wherein
said connection performing unit further receives contents specifying information for specifying the content from the user via said relay and determines whether or not the connection to the external terminal can be made on the basis of the received contents specifying information, and
said connection performing unit sends the content to the external terminal in case said connection determining unit issues a connection allowance.

12. An information providing apparatus as claimed in claim 8, further comprising:
an information format corresponding unit for corresponding the kind of terminal to converted information format, and
a converting unit for receiving the kind of the external terminal and converting the content, which should be provided to the user, into the information format which can be processed by the external terminal by using said information format corresponding unit, wherein
said connection performing unit sends the converted content to the external terminal.

13. An information providing apparatus as claimed in claim 8 further comprising a contents managing unit connected to a simulation system performing a simulation computation on the closed network for regularly acquiring the computation result of the simulation and/or the computation process as the content, wherein
said connection performing unit provides the computation result and/or the computation process acquired by said contents managing unit to the external terminal.

14. An information providing apparatus as claimed in claim 8 further comprising:
a contents request receiving unit for receiving mail request information which requests mail sent to the user;
a contents managing unit for managing the mail sent to an internal terminal of the user connected to the closed network; and
a converting unit for converting the mail into a language which can be interpreted by a Web browser, wherein
said connection performing unit converts the mail sent to the internal terminal of the user into the language which can be interpreted by the Web browser and send it to the external terminal in case a mail request information.

15. A connecting method for connecting an information providing apparatus in a closed network and an external terminal, which is a user terminal, connected to an open network, the open network being connected to the closed network via a router, comprising the steps of:
receiving and storing a user identifying information for identifying the user as a request for connecting to the information providing apparatus from an external terminal by a relay in the open network;
sending a connection confirming request, which has an indication to confirm presence of a connection request from the external terminal, regularly to the relay by the information providing apparatus;
outputting the user identifying information stored in a connection request holding unit to the information providing apparatus in case the connection confirming request is received from said information providing apparatus by the relay; and
receiving the user identifying information from the relay, determining whether or not a connection to the external terminal can be made on the basis of the user identifying information; and connecting to the external terminal by the information providing apparatus.

16. A machine readable medium storing thereon a computer program for connecting to an external terminal, which is a user terminal, can be connected to an open network and can not be connected to a closed network, from a closed network connected to the open network via a router though a relay in the open network, said program comprises:
a connection request confirming function for regularly requesting a user identifying information received by the relay from the external terminal as a request for connecting to the computer to the relay;
a connection determining function for receiving the user identifying information from the relay and determining whether or not a connection to the external terminal can be made on the basis of the user identifying information; and
a connection performing unit for making a connection to the external terminal on the basis of the determination result of the connection determining function.
